(19) United States
(12) Patent Application Publication
(10) Pub. No.: US 2026/0088767 A1
(43) Pub. Date: Mar. 26, 2026

(54) Current-Sharing Amplifier Circuitry

(71) Applicant: Apple Inc., Cupertino, CA (US)

(72) Inventors: James Mawdsley, Costa Mesa, CA (US); Hongrui Wang, San Jose, CA (US); Abbas Komijani, Mountain View, CA (US); Milad Darvishi, San Diego, CA (US)

(21) Appl. No.: 18/896,728

(22) Filed: Sep. 25, 2024

(51) Int. Cl. H03F 1/02; H03F 3/24; H04B 1/04

(52) U.S. Cl. CPC H03F 1/0222; H03F 3/245; H04B 1/04; H03F 2200/451; H04B 2001/0408

(57) ABSTRACT

Wireless communication circuitry may include amplifier circuitry. Amplifier circuitry may include multiple amplifier stages. Some amplifier stages may be coupled along different parallel radio-frequency paths. Some amplifier stages may be coupled serially along the same radio-frequency path. Amplifier circuitry may be configured to provide current-sharing between amplifier stages coupled along parallel radio-frequency paths, provide dynamically adjustable relative voltage headroom between current-sharing amplifier stages, and/or provide switching to operate in current-sharing and non-current-sharing modes.

### FIELD

This disclosure relates generally to electronic devices such as electronic devices with wireless communications circuitry.

### BACKGROUND

Electronic devices are often provided with wireless communications capabilities. An electronic device with wireless communications capabilities has wireless communications circuitry with one or more antennas. Radio-frequency transceiver circuitry in the wireless communications circuitry uses the antennas to transmit and receive radio-frequency signals.

Wireless communications circuitry can include amplifier circuitry. It can be challenging to design amplifier circuitry for the wireless communications circuitry.

### SUMMARY

An electronic device may include wireless communications circuitry. The wireless communications circuitry may include amplifier circuitry. The amplifier circuitry may include multiple amplifier stages, each containing one or more common-source amplifiers, one or more common-gate amplifiers, one or more cascode amplifiers, and/or other types of amplifier(s). Some amplifier stages may be coupled serially along the same radio-frequency paths with respect to each other. Some amplifier stages may be coupled along different parallel radio-frequency paths with respect to each other.

In some illustrative configurations described herein as examples, amplifier stages coupled along different parallel radio-frequency paths may be configured to perform current-sharing, current-sharing amplifier stages may exhibit dynamically adjustable supply voltage headroom (e.g., based on active antenna resonating elements, amplifier gain, etc.), and/or amplifier stages may be operable in current-sharing and non-current-sharing modes.

An aspect of the disclosure provides wireless communications circuitry. The wireless communications circuitry can include a first amplifier stage and a second amplifier stage. The first amplifier stage is configured to receive first radio-frequency signals and operate with a first and second supply voltages to process the first radio-frequency signals. The second amplifier stage is coupled to the first amplifier stage and configured to receive second radio-frequency signals and operate with the second supply voltage and a reference voltage to process the second radio-frequency signals. The first supply voltage and the reference voltage are fixed voltages. The second supply voltage is a variable voltage.

An aspect of the disclosure provides radio-frequency amplifier circuitry. The radio-frequency amplifier circuitry can include a first amplifier stage, a second amplifier stage, a current-sharing path that couples the first amplifier stage to the second amplifier stage and that is configured to provide a supply voltage to the second amplifier stage, and switching circuitry coupled along the current-sharing path and configured to exhibit a first state in which the current-sharing path is enabled and a second state in which the current-sharing path is disabled.

An aspect of the disclosure provides wireless communications circuitry. The wireless communications circuitry can include first amplifier circuitry coupled along a first radio-frequency path and second amplifier circuitry coupled to the first amplifier circuitry and coupled along a second radio-frequency path that is parallel to the first radio-frequency path. The first amplifier circuitry is configured to receive a first supply voltage, generate a second supply voltage, and process a first radio-frequency signal based on the first and second supply voltages. The second amplifier circuitry is configured to receive the second supply voltage from the first amplifier circuitry, receive a reference voltage, and process a second radio-frequency signal based on the second supply voltage and the reference voltage.

### BRIEF DESCRIPTION OF THE DRAWINGS

FIG. 1 is a diagram of an illustrative electronic device having wireless communications circuitry in accordance with some embodiments.

FIG. 2 is a diagram of illustrative wireless communications circuitry having amplifier circuitry in accordance with some embodiments.

FIG. 3 is a diagram of two illustrative amplifier stages along respective parallel radio-frequency paths configured to perform current-sharing in accordance with some embodiments.

FIG. 4 is a circuit diagram of illustrative first and second power amplifier circuitry along respective parallel radio-frequency paths coupled to each other by a current-sharing path in accordance with some embodiments.

FIG. 5 is a diagram of two illustrative amplifier stages configured to perform current-sharing with dynamic amplifier headroom adjustment in accordance with some embodiments.

FIG. 6 is a diagram of an illustrative control circuit for dynamically adjusting the supply voltage shared between current-sharing amplifier stages in accordance with some embodiments.

FIGS. 7 and 8 are diagrams of two current-sharing amplifier stages along respective parallel radio-frequency paths configurable in current-sharing and non-current-sharing modes in accordance with some embodiments.

FIGS. 9 and 10 are diagrams of two current-sharing amplifier stages coupled serially along a same radio-frequency path configurable in current-sharing and non-current-sharing modes in accordance with some embodiments.

### DETAILED DESCRIPTION

An electronic device may be provided with wireless communications circuitry. The wireless communications circuitry may include amplifier circuitry for processing or more specifically amplifying radio-frequency signals. The amplifier circuitry may include multiple amplifier stages each containing one or more amplifiers such as common-source amplifier(s), common-gate amplifier(s), cascode amplifier(s) and/or other types of amplifiers. Current-sharing between amplifier stages may be used to reduce power consumption. However, certain current-sharing schemes (e.g., between amplifier stages that are coupled along the same radio-frequency path) may exhibit undesired performance and/or design issues (e.g., imbalance of bias currents between current-sharing stages, reduced linearity of current-sharing amplifier stages, inflexible use of headroom between current-sharing stages, design inter-dependencies between current-sharing stages, etc.).

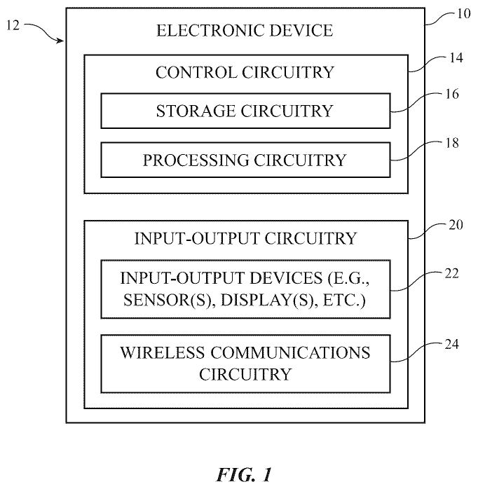

To mitigate one or more of these issues and generally implement improved current-sharing schemes, amplifier circuitry may include amplifier stages coupled along different parallel radio-frequency paths and configured to perform current-sharing, may include current-sharing amplifier stages that exhibit dynamically adjustable supply voltage headroom (e.g., based on active antenna resonating elements, amplifier gain, etc.), and/or may include amplifier stages that are operable in current-sharing and non-current-sharing modes. An illustrative electronic device having amplifier circuitry with amplifier stages configured to perform current-sharing (e.g., in the manner described above) is shown in FIG. 1.

FIG. 1 is a diagram of an illustrative electronic device such as electronic device 10. Electronic device 10 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram of FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, parts or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include one or more microprocessors, microcontrollers, digital signal processors, host processors, baseband processor integrated circuits, application processors, application specific integrated circuits, central processing units (CPUs), general purpose processors, or other types of processors. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G New Radio (NR) protocols, etc.), MIMO protocols, antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, electronic pencil (e.g., a stylus), and joysticks, and other input-output devices may be coupled to device 10 using wired or wireless connections (e.g., some of input-output devices 22 may be peripherals that are coupled to a main processing unit or other portion of device 10 via a wired or wireless link).

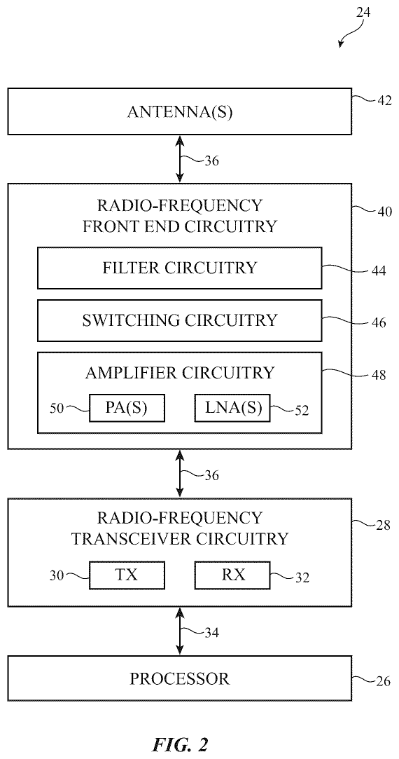

Input-output circuitry 20 may include wireless communications circuitry such as wireless communications circuitry 24 (sometimes referred to herein as wireless circuitry 24) for wirelessly conveying radio-frequency signals. FIG. 2 is a diagram showing illustrative components within wireless circuitry 24. As shown in FIG. 2, wireless circuitry 24 may include one or more processors such as processor 26, radio-frequency (RF) transceiver circuitry such as radio-frequency transceiver circuitry 28, radio-frequency front end circuitry such as radio-frequency front end circuitry 40 (which, when integrated, may sometimes be referred to as front end module 40), and one or more antennas such as antenna(s) 42. Processor 26 may be a baseband processor, application processor, general purpose processor, microprocessor, microcontroller, digital signal processor, host processor, or other type of processor. If desired, processor 26 may be implemented as part of control circuitry 14. Processor 26 may be coupled to transceiver circuitry 28 over path 34. Transceiver circuitry 28 may be coupled to antenna(s) 42 via radio-frequency transmission line path(s) 36. Radio-frequency front end circuitry 40 may be disposed along (e.g., on) radio-frequency transmission line path(s) 36 between transceiver circuitry 28 and antenna(s) 42.

In the example of FIG. 2, wireless circuitry 24 is illustrated as including a single processor 26, a single instance of transceiver circuitry 28, a single instance of front end circuitry 40, and a single set of antenna(s) 42 for the sake of clarity. In general, wireless circuitry 24 may include any number of processors 26, any number of instances of transceiver circuitry 28, any number of instances of front end circuitry 40, and any number of sets of antenna(s) 42. Each processor 26 may be coupled to one or more transceivers (e.g., instances of transceiver circuitry 28) over respective paths 34. Each transceiver 28 may include a transmitter circuit 30 configured to output uplink signals to antenna(s) 42, may include a receiver circuit 32 configured to receive downlink signals from antenna(s) 42, and may be coupled to one or more antennas 42 over respective radio-frequency transmission line paths 36. Each radio-frequency transmission line path 36 may have respective front end circuitry 40 disposed thereon. If desired, two or more instances of (different types of) front end circuitry 40 may be disposed on the same radio-frequency transmission line path 36. If desired, one or more of the radio-frequency transmission line paths 36 in wireless circuitry 24 may be implemented without any front end circuitry 40 disposed thereon.

Antenna(s) 42 may be formed using any desired antenna structures. For example, antenna(s) 42 may each be an antenna with an antenna resonating element that is formed from loop antenna structures, patch antenna structures, inverted-F antenna structures, slot antenna structures, planar inverted-F antenna structures, helical antenna structures, monopole antennas, dipole antennas, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

Each radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency signals within device 10 (FIG. 1). These transmission lines may include coaxial cables, microstrip transmission lines, stripline transmission lines, edge-coupled microstrip transmission lines, edge-coupled stripline transmission lines, transmission lines formed from combinations of transmission lines of these types, etc. If desired, transmission lines in radio-frequency transmission line paths 36 may be integrated into rigid printed circuit boards and/or flexible printed circuit substrates.

In performing wireless signal transmission, processor(s) 26 may provide transmit signals (e.g., digital or baseband signals) to transceiver circuitry 28 over path 34. Transceiver circuitry 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio-frequencies prior to transmission over antenna 42. The example of FIG. 2 in which processor 26 communicates with transceiver circuitry 28 is merely illustrative. In general, transceiver circuitry 28 may communicate with a baseband processor, an application processor, general purpose processor, a microcontroller, a microprocessor, or one or more processors within circuitry 18 (e.g., implementing the functions of processor 26). Transceiver circuitry 28 may also include digital-to-analog converter (DAC) and/or analog-to-digital converter (ADC) circuitry for converting signals between digital and analog domains. Transceiver circuitry 28 may use transmitter (TX) 30 to transmit the radio-frequency signals over antenna(s) 42 via radio-frequency transmission line path 36 and front end circuitry 40. Antenna(s) 42 may transmit the radio-frequency signals to external wireless equipment by radiating the radio-frequency signals into free space.

In performing wireless reception, antenna(s) 42 may receive radio-frequency signals from the external wireless equipment. The received radio-frequency signals may be conveyed to transceiver circuitry 28 via radio-frequency transmission line path 36 and front end circuitry 40. Transceiver circuitry 28 may include circuitry such as receiver (RX) 32 for receiving signals from front end circuitry 40 and for converting the received radio-frequency signals into corresponding baseband signals. For example, transceiver circuitry 28 may include mixer circuitry for down-converting (or demodulating) the received radio-frequency signals to baseband frequencies prior to conveying the received signals to processor 26 (or control circuitry 18 implementing the function of processor 26) over path 34.

Radio-frequency front end circuitry 40 may operate on the radio-frequency signals conveyed (transmitted and/or received) over radio-frequency transmission line path 36. Front end circuitry 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip.

Filter circuitry 44, switching circuitry 46, amplifier circuitry 48, and other circuitry may be disposed along (e.g., on) radio-frequency transmission line path 36, may be incorporated into a front end module, and/or may be incorporated into antenna 42 (e.g., to support antenna tuning, to support operation in desired frequency bands, etc.). At least some of these components may form antenna tuning components that are adjusted (e.g., using control circuitry 14) to adjust the frequency response and wireless performance of antenna 42 over time.

While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver circuitry 28 (e.g., a host processor on transceiver circuitry 28) may form a part of control circuitry 14. Control circuitry 14 (e.g., portions of control circuitry 14 formed on processor 26, portions of control circuitry 14 formed on transceiver circuitry 28, and/or portions of control circuitry 14 that are separate from wireless circuitry 24) may provide control signals (e.g., over one or more control paths in device 10) that control the operation of front end circuitry 40.

Transceiver circuitry 28 may be separate from front end circuitry 40. For example, transceiver circuitry 28 may be formed on another substrate such as the main logic board of device 10, a rigid printed circuit board, or flexible printed circuit different than the one on which front end circuitry 40 is provided.

Radio-frequency transceiver circuitry 28 may handle transmission and/or reception of radio-frequency signals in various radio-frequency communications bands. For example, radio-frequency transceiver circuitry 28 may handle radio-frequency signals in wireless local area network (WLAN) communications bands such as the 2.4 GHz and 5 GHz Wi-Fi® (IEEE 802.11) bands, wireless personal area network (WPAN) communications bands such as the 2.4 GHZ Bluetooth® communications band, cellular telephone communications bands such as a cellular low band (LB) (e.g., 600 to 960 MHz), a cellular low-midband (LMB) (e.g., 1400 to 1550 MHz), a cellular midband (MB) (e.g., from 1700 to 2200 MHz), a cellular high band (HB) (e.g., from 2300 to 2700 MHz), a cellular ultra-high band (UHB) (e.g., from 3300 to 5000 MHz), or other cellular communications bands between about 600 MHz and about 5000 MHz (e.g., 3G bands, 4G LTE bands, 5G New Radio Frequency Range 1 (FR1) bands below 10 GHZ, 5G New Radio Frequency Range 2 (FR2) bands at millimeter and centimeter wavelengths between 20 and 60 GHz, etc.), a near-field communications (NFC) band (e.g., at 13.56 MHz), satellite navigations bands (e.g., an L1 global positioning system (GPS) band at 1575 MHz, an L5 GPS band at 1176 MHz, a Global Navigation Satellite System (GLONASS) band, a BeiDou Navigation Satellite System (BDS) band, etc.), an ultra-wideband (UWB) communications band supported by the IEEE 802.15.4 protocol and/or other UWB communications protocols (e.g., a first UWB communications band at 6.5 GHZ and/or a second UWB communications band at 8.0 GHZ), and/or any other desired communications bands. The communications bands handled (e.g., covered) by radio-frequency transceiver circuitry 28 may sometimes be referred to herein as frequency bands or simply as “bands,” and may span corresponding ranges of frequencies.

As described above, front end circuitry 40 may include amplifier circuitry 48 (sometimes referred to as radio-frequency amplifier circuitry). In some illustrative configurations described herein as examples, amplifier circuitry 48 (e.g., power amplifier circuitry 50 or low-noise amplifier circuitry 52) may include multiple amplifier stages (sometimes referred to as multiple instances of amplifier circuitry, e.g., first amplifier circuitry, second amplifier circuitry, etc.). Each amplifier stage may be formed from any suitable type of amplifier. As examples, each amplifier stage may include common-source amplifier(s), common-gate amplifier(s), cascode amplifier(s), and/or other type(s) of amplifier(s). Amplifier circuitry 48 (e.g., power amplifier circuitry 50 or low-noise amplifier circuitry 52) may include any suitable number of amplifier stages (e.g., two stages, three stages, four stages, eight stages, more than eight stages, etc.). Some amplifier stages may be coupled serially (e.g., cascaded) along the same radio-frequency path with respect to each other. Some amplifier stages may be coupled along different (e.g., parallel) radio-frequency paths with respect to each other. Different amplifier stages may be implemented on the same integrated circuit die and/or may be implemented separately using multiple integrated circuit dies coupled to each other.

Illustrative configurations in which amplifier circuitry 48 refers to amplifier circuitry in radio-frequency receive path(s) (e.g., low-noise amplifier circuitry 52) are sometimes described herein as examples. If desired, the embodiments described herein may similarly be applied to amplifier circuitry in radio-frequency transmit path(s) (e.g., power amplifier circuitry 50).

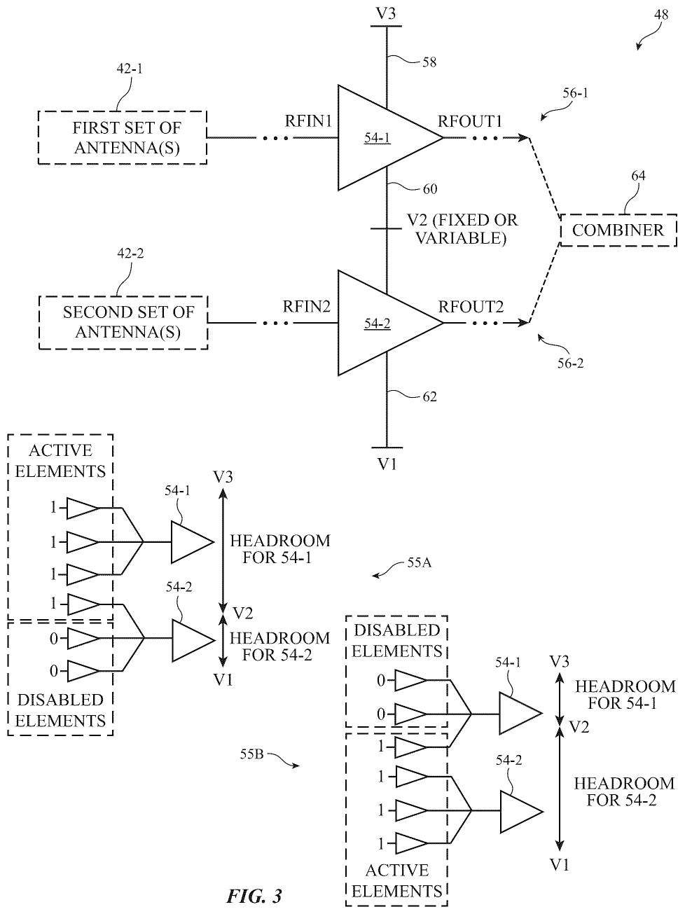

FIG. 3 is a diagram of illustrative amplifier circuitry 48 (e.g., receive path amplifier circuitry such as amplifier circuitry 52 in FIG. 2). In particular, amplifier circuitry 48 may include a first amplifier stage 54-1 coupled along (e.g., on, at a location along, etc.) a first radio-frequency path 56-1 and a second amplifier stage 54-2 coupled along (e.g., on, at a location along, etc.) a second radio-frequency path 56-2. Multiple other radio-frequency components (e.g., additional radio-frequency amplifier stage(s)) may also be coupled along radio-frequency paths 56-1 and 56-2, upstream or downstream from amplifier stages 54-1 and 54-2. Radio frequency components such as amplifier stages 54-1 and 54-2 on different radio-frequency paths 56-1 and 56-2 may operate on or otherwise process radio-frequency signals in parallel (e.g., different radio-frequency signals on different radio-frequency paths at the same time).

Amplifier stage 54-1 may have a radio-frequency signal input (port) RFIN1 coupled to a first portion of radio-frequency path 56-1 and may have a radio-frequency signal output (port) RFOUT1 coupled to a second portion of radio-frequency path 56-1. Amplifier stage 54-2 may have a radio-frequency signal input (port) RFIN2 coupled to a first portion of radio-frequency path 56-2 and may have a radio-frequency signal output (port) RFOUT2 coupled to a second portion of radio-frequency path 56-2.

To improve power consumption while mitigating issues (e.g., imbalance of bias currents between current-sharing stages, reduced linearity of current-sharing amplifier stages, inflexible use of headroom between current-sharing stages, design inter-dependencies between current-sharing stages) resulting from current-sharing between cascaded amplifier stages (e.g., two amplifier stages in the same radio-frequency path), parallel amplifier stages 54-1 and 54-2 may be configured to perform current-sharing.

In particular, amplifier stage 54-1 may have a first supply voltage terminal coupled, via voltage supply path 58, to a voltage source providing supply voltage V3 and may have a second supply voltage terminal coupled, via current-sharing path 60, to amplifier stage 54-1. Supply voltage V2 may be provided at the second supply voltage terminal of amplifier stage 54-1. Accordingly, amplifier stage 54-1 may use supply voltages V3 and V2 to process (e.g., amplify or otherwise operate on) radio-frequency signals received at input RFIN1 and output the processed (e.g., amplified) versions of the radio-frequency signals at output RFOUT1. As such, the difference between supply voltages V3 and V2 may sometimes be referred to herein as the supply voltage headroom, or simply headroom, for amplifier stage 54-1.

Amplifier stage 54-2 may have a first supply voltage terminal coupled, via voltage supply path 62, to a voltage source providing a supply voltage V1 (e.g., a reference voltage such as a ground voltage) and may have a second supply voltage terminal coupled, via current-sharing path 60, to amplifier stage 54-2. Supply voltage V2 may be provided at the second supply voltage terminal of amplifier stage 54-2. Accordingly, amplifier stage 54-2 may use voltages V2 and V1 to process (e.g., amplify or otherwise operate on) radio-frequency signals received at input RFIN2 and output the processed (e.g., amplified) versions of the radio-frequency signals at output RFOUT2. As such, the difference between supply voltages V2 and V1 may sometimes be referred to herein as the supply voltage headroom, or simply headroom, for amplifier stage 54-2.

As described above, current-sharing between analogous amplifier stages in respective radio-frequency paths may overcome the issues with current-sharing between cascading amplifier stages in the same radio-frequency path. As one particular advantage, among other advantages, because the beat currents generated at parallel amplifier stages (e.g., amplifier stages 54-1 and 54-2) conveyed via the current-sharing path are similar in terms of phase and magnitude, the linearity of the current-sharing scheme between parallel amplifier stages is less dependent on having a low impedance at the current-sharing path, thereby omitting the need to separately control impedance at the current-sharing path.

Supply voltages V3 and V1 may be fixed voltages, where voltage V3 is at a higher voltage level than voltage V1. For example, supply voltage V3 may be a drain-side supply voltage and supply voltage V1 may be a ground or other type of reference voltage (e.g., another supply voltage). In some illustrative configurations described herein as an example, supply voltage V2 may be a variable voltage. The voltage level of supply voltage V2 may be varied (e.g., controlled) based on the operation of the upper amplifier stage (e.g., amplifier stage 54-1). However, if desired in other configurations, supply voltage V2 may be a fixed voltage, e.g., enforced by a voltage source providing voltage V2 that is coupled to current-sharing path 60. Voltage V2, whether fixed or variable may have voltage level(s) between the voltage levels of voltage V3 and V1.

In illustrative configurations in which the voltage level of voltage V2 is variable, the second supply voltage terminal of amplifier stage 54-1 may provide the voltage level of voltage V2. The provided voltage level of voltage V2 may be supplied to the second supply voltage terminal of amplifier stage 54-1 for use in processing radio-frequency signals.

Configurations in which radio-frequency paths 56-1 and 56-2 are receive paths (e.g., conveying signals received from antenna(s) 42 to transceiver circuitry 28) are sometimes described herein as examples. In one illustrative arrangement, radio-frequency path 56-1 (e.g., amplifier stage 54-1, at input RFIN1) may be coupled to a first set of antenna(s) 42-1 and may receive radio-frequency signals from antenna(s) 42-1, while radio-frequency path 56-2 (e.g., amplifier stage 54-2, at input RFIN2) may be coupled to a second set of antenna(s) 42-2 and may receive radio-frequency signals from antenna(s) 42-2. If desired, radio-frequency signals from multiple antennas 42-1 may have been combined prior to reaching input RFIN1 of amplifier stage 54-1, and similarly, radio-frequency signals from multiple antennas 42-2 may have been combined prior to reaching input RFIN1 of amplifier stage 54-1.

Antennas 42-1 and 42-2 may each be an instance of antenna 42 in FIG. 2 and may collectively form an antenna array (e.g., a steerable phased antenna array). In particular, the set of antenna(s) 42-1 may form a first portion of the antenna array and the set of antenna(s) 42-2 may form a second portion of the antenna array.

Radio-frequency signals from antenna(s) 42-1 may be received, processed (e.g., using supply voltages V3 and V2), and output by amplifier stage 54-1. Radio-frequency signals from antenna(s) 42-2 may be received, processed (e.g., using supply voltages V2 and V1), and output by amplifier stage 54-2. A radio-frequency combiner 64 may be coupled to outputs RFOUT1 and RFOUT2 and may combine the radio-frequency signals from radio-frequency paths 56-1 and 56-2, such as the processed versions of radio-frequency signals from antenna(s) 42-1 and 42-2 from paths 56-1 and 56-2, respectively.

In this illustrative configuration, the voltage level of supply voltage V2 may be varied or controlled based on the number of active antennas in antennas 42-1 and/or antennas 42-2. In particular, processing large (magnitude) signals can cause a more difficult linearity scenario for an amplifier stage. To improve amplifier performance (e.g., linearity) when processing large signals, headroom for the amplifier stage may be adjusted (e.g., increased by adjusting the voltage level of supply voltage V2).

Still referring to FIG. 3, in a first scenario 55A, the number of antenna(s) 42-1 that are active (e.g., enabled) and are receiving radio-frequency signals conveyed to amplifier stage 54-1 (or generally the number of enabled parallel upstream elements coupled to amplifier stage 54-1) may be greater than the number of antenna(s) 42-2 that are active (e.g., enabled) and are receiving radio-frequency signals conveyed to amplifier stage 54-2 (or generally the number of enabled parallel upstream elements coupled to amplifier stage 54-2). In the illustrative example of scenario 55A shown in FIG. 3, three enabled (out of three total) upstream elements (e.g., three antennas 42-1 enabled for passing received radio-frequency signals to amplifier stage 54-1) may be coupled to amplifier stage 54-1, while only one enabled (out of three total) upstream elements (e.g., one antenna 42-2 enabled for passing received radio-frequency signals to amplifier stage 54-2) may be coupled to amplifier stage 54-2.

In this first scenario 55A, amplifier stage 54-1 may be configured to handle a larger signal (e.g., a three-times larger signal) than amplifier stage 54-2 and may therefore be allocated a larger headroom than amplifier stage 54-2. Accordingly, amplifier stage 54-1 may be controlled to provide a voltage level for voltage V2 that is less than half of the difference between voltages V3 and V1, thereby providing more headroom to amplifier stage 54-1 than amplifier stage 54-2.

In a second scenario 55B, the number of antenna(s) 42-1 that are active (e.g., enabled) and are receiving radio-frequency signals conveyed to amplifier stage 54-1 (or generally the number of enabled parallel upstream elements coupled to amplifier stage 54-1) may be less than the number of antenna(s) 42-2 that are active (e.g., enabled) and are receiving radio-frequency signals conveyed to amplifier stage 54-2 (or generally the number of enabled parallel upstream elements coupled to amplifier stage 54-2). In the illustrative example of scenario 55B shown in FIG. 3, only one enabled (out of three total) upstream elements (e.g., one antenna 42-1 enabled for passing received radio-frequency signals to amplifier stage 54-1) may be coupled to amplifier stage 54-1, while three enabled (out of three total) upstream elements (e.g., three antennas 42-2 enabled for passing received radio-frequency signals to amplifier stage 54-2) may be coupled to amplifier stage 54-2.

In this second scenario 55B, amplifier stage 54-1 may be configured to handle a smaller signal (e.g., a three-times smaller signal) than amplifier stage 54-2 and may therefore be allocated a smaller headroom than amplifier stage 54-2. Accordingly, amplifier stage 54-1 may be controlled to provide a voltage level for voltage V2 that is greater than half of the difference between voltages V3 and V1, thereby providing more headroom to amplifier stage 54-2 than amplifier stage 54-1.

In a third scenario, in which the number of antenna(s) 42-1 that are active (e.g., enabled) and are receiving radio-frequency signals conveyed to amplifier stage 54-1 is the same as the number of antenna(s) 42-2 that are active (e.g., enabled) and are receiving radio-frequency signals conveyed to amplifier stage 54-2, amplifier stage 54-1 may be configured to handle a similar magnitude signal similar to that handled by amplifier stage 54-2 and may therefore be allocated the same headroom as amplifier stage 54-2. Accordingly, amplifier stage 54-1 may be controlled to provide a voltage level for voltage V2 that is half of the difference between voltages V3 and V1, thereby providing the same headroom to amplifier stage 54-2 and amplifier stage 54-1.

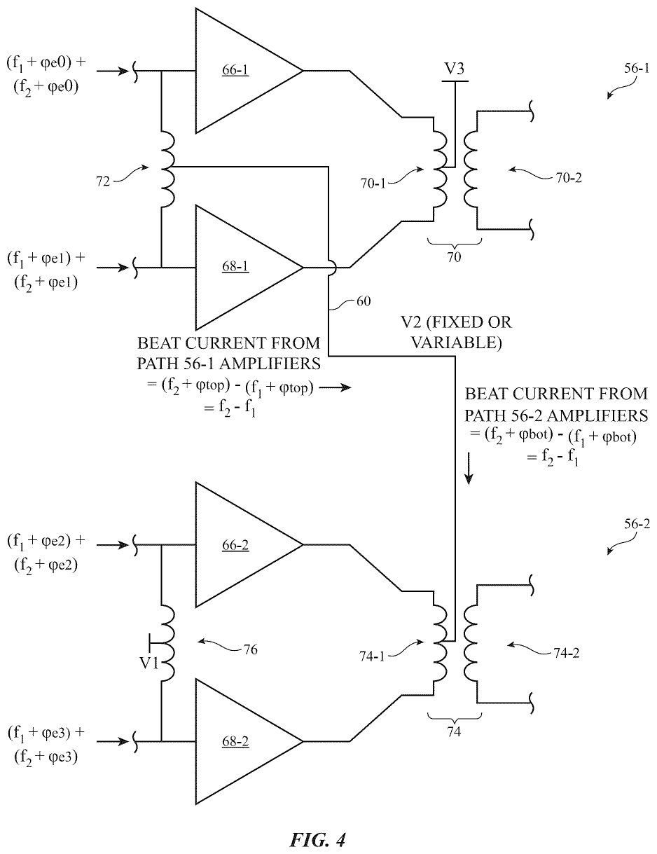

FIG. 4 is a circuit diagram of an illustrative implementation of current-sharing across parallel amplifier stages. As shown in FIG. 4, amplifier circuitry may include a first amplifier stage 66-1 and a second amplifier stage 68-1 having respective radio-frequency inputs through which respective radio-frequency signals are received. Amplifier stages 66-1 and 68-1 may have respective outputs, for outputting processed radio-frequency signals, that are combined at transformer 70 having a first inductor 70-1 (e.g., a first winding) and a second inductor 70-2 (e.g., a first winding). An additional inductor 72 may be coupled between the inputs of amplifier stages 66-1 and 68-1.

The amplifier stage of FIG. 4 may further include a third amplifier stage 66-2 and a fourth amplifier stage 68-2 having respective radio-frequency inputs through which respective radio-frequency signals are received. Amplifier stages 66-2 and 68-2 may have respective outputs, for outputting processed radio-frequency signals, that are combined at transformer 74 having a first inductor 74-1 (e.g., a first winding) and a second inductor 74-2 (e.g., a first winding). An additional inductor 76 may be coupled between the inputs of amplifier stages 66-2 and 68-2.

In the example of FIG. 4, amplifier stages 66-1 and 68-1 may be referred to as being coupled along a same radio-frequency path 56-1 as their outputs are combined at transformer 70. Accordingly, in this example, amplifier stages 66-1 and 68-1 each serve as an instance of amplifier stage 54-1 in FIG. 3. Similarly, amplifier stages 66-2 and 68-2 may be referred to as being coupled along a same radio-frequency path 56-2 as their outputs are combined at transformer 74. Accordingly, in this example, amplifier stages 66-2 and 68-2 each serve as an instance of amplifier stage 54-2 in FIG. 3.

To provide current sharing between amplifier stages in the first radio-frequency path (e.g., stages 66-1 and 68-1) and amplifier stages in the second radio-frequency path (e.g., stages 66-2 and 68-2), inductor 70-1 may be coupled to a voltage source providing supply voltage V3, inductor 72 may be coupled to inductor 74-1 via current-sharing path 60, and inductor may be coupled to a voltage source providing supply voltage V1 (e.g., a reference voltage). Accordingly, the supply current may flow from inductor 70-1 to inductor 72 through stages 66-1 and 66-2, may be provided to inductor 74-1 through path 60, and may flow from inductor 74-1 to inductor 76 through stages 66-2 and 68-2.

As demonstrated by the example of FIG. 4, the direct current (DC) supply current path may overlap the path for conveying radio-frequency signals (e.g., DC supply current and radio-frequency signals may share at least some path portions). Accordingly, the diagram of FIG. 3 showing separate supply voltage terminals and radio-frequency signal inputs-outputs is merely illustrative of the conceptual differences in the uses and/or functions of supply voltage and radio-frequency signals in the context of amplifiers. The underlying physical paths may be shared or separate depending on amplifier architecture implementing the amplifier stages.

Additionally, as demonstrated by the example of FIG. 4, the amplifiers of paths 56-1 and 56-2 (e.g., amplifiers 66-1 and 68-1 of path 56-1, and amplifiers 66-2 and 68-2 of path 56-2) may have or exhibit the same (or similar) beat current (e.g., in terms of phase and magnitude) along path 60. Accordingly, current sharing between the amplifiers of paths 56-1 and 56-2 does not create any cross-modulation. This removes the need to have a low impedance low-dropout regulator (LDO) coupled to path 60 (e.g., the middle node with voltage V2).

The illustrative configuration of FIG. 4 is merely illustrative. Certain components (e.g., filtering components, impedance matching components, etc.) have been omitted from FIG. 4 in order to not unnecessarily obscure the current embodiments and may be included in the amplifier circuitry of FIG. 4.

While FIG. 3 provides examples in which current-sharing amplifier stages coupled along (e.g., on, at a location along, etc.) parallel radio-frequency paths can be configured with controllable amplifier stage headroom (e.g., by providing supply voltage V2 at different voltage levels), these examples are merely illustrative. If desired, other types of current-sharing amplifier stages may similarly be configured with controllable amplifier stage headroom.

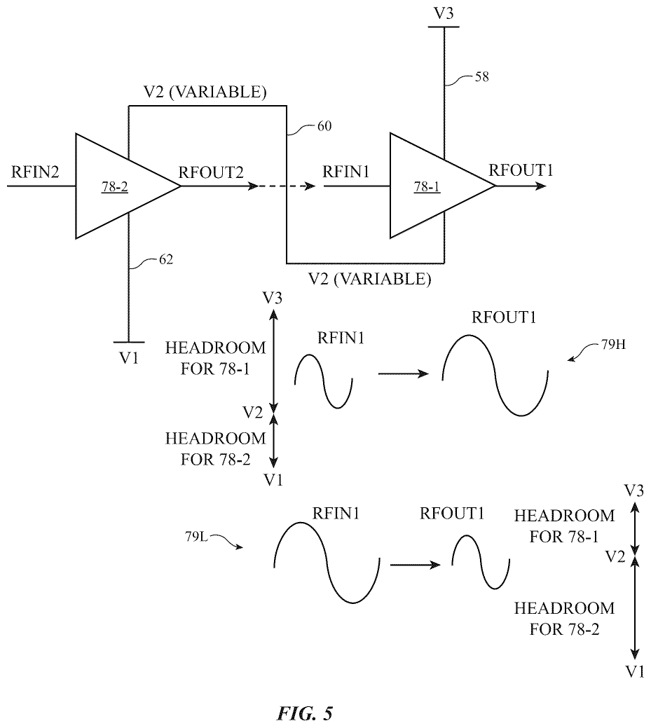

FIG. 5 is a diagram of two illustrative currently-sharing amplifier stages 78-1 and 78-2. In the example of FIG. 5, amplifier stage 78-1 may receive radio-frequency signals at radio-frequency signal input RFIN1, process the received radio-frequency signals using the amplifier stage headroom provided by supply voltages V3 and V2, and output the processed versions of the radio-frequency signals at radio-frequency signal output RFOUT1. Amplifier stage 78-2 may receive radio-frequency signals at radio-frequency signal input RFIN2, process the received radio-frequency signals using the amplifier stage headroom provided by supply voltages V2 and V1, and output the processed versions of the radio-frequency signals at radio-frequency signal output RFOUT2. Amplifier stage 78-1 may be controlled to provide varying voltage levels for supply voltage V2 (provided on current-sharing path 60) to amplifier stage 78-1 to adjust the headroom of amplifier stages 78-1 and 78-2 (e.g., while voltage levels of voltages V3 and V1 provided via paths 58 and 62, respectively, remain fixed).

In some illustrative configurations described herein as an example, amplifier stages 78-1 and 78-2 may be two amplifier stages coupled serially along a same radio-frequency path. In particular, amplifier stage 78-1 may be an amplifier stage downstream from amplifier stage 78-2. Accordingly, radio-frequency signals received at port RFIN1 may be based on (e.g., the same as or processed versions of) the radio-frequency signals output at port RFOUT2.

The voltage level of supply voltage V2 may be varied or controlled based on any number and combination of factors, such as the types (e.g., large or small) radio-frequency signals to be processed by the amplifier stages (as described in connection with FIG. 3), the desired operational characteristics of the amplifier stages, etc. As one example described in connection with FIG. 5, the voltage level of supply voltage V2 may be varied or controlled based on the desired gain to be provided by amplifier stage 78-1 (e.g., whether amplifier stage 78-1 is operating in a high gain mode or a low gain mode).

In a first scenario 79H, amplifier stage 78-1 may be operating in a high gain mode (e.g., to provide a gain to radio-frequency signals that is greater than the gain provided in a low gain mode) and/or may be operating with a gain greater than the gain with which amplifier stage 78-2 is operating. In this first scenario, amplifier stage 78-1 may be allocated a larger headroom than amplifier stage 78-2. Accordingly, amplifier stage 78-1 may be controlled to provide a voltage level for voltage V2 that is less than half of the difference between voltages V3 and V1, thereby providing more headroom to amplifier stage 78-1 than amplifier stage 78-2.

In a second scenario 79L, amplifier stage 78-1 may be operating in a low gain mode (e.g., to provide a gain to radio-frequency signals that is less than the gain provided in a high gain mode) and/or may be operating with a gain less than the gain with which amplifier stage 78-2 is operating. In this second scenario, amplifier stage 78-1 may be allocated a smaller headroom than amplifier stage 78-2. Accordingly, amplifier stage 78-1 may be controlled to provide a voltage level for voltage V2 that is greater than half of the difference between voltages V3 and V1, thereby providing more headroom to amplifier stage 78-2 than amplifier stage 78-1.

In a third scenario, in which amplifier stages 78-1 and amplifier stage 78-2 operate with similar (e.g., the same) gain settings, amplifier stage 78-1 may be allocated the same headroom as amplifier stage 78-2. Accordingly, amplifier stage 78-1 may be controlled to provide a voltage level for voltage V2 that is half of the difference between voltages V3 and V1, thereby providing the same headroom to amplifier stage 78-2 and amplifier stage 78-1.

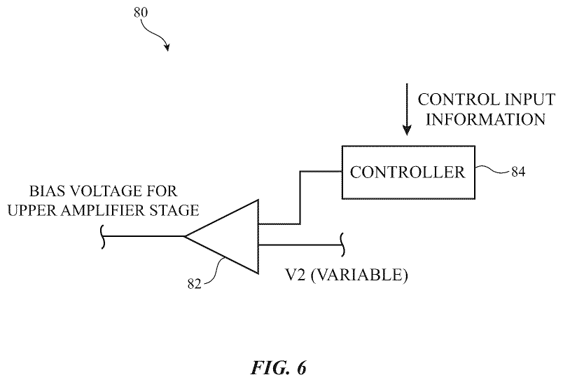

FIG. 6 is a diagram of an illustrative control circuit 80 configured to control the upper amplifier stage (e.g., amplifier stage 54-1 in FIG. 3, amplifier stage 66-1 or 68-1 in FIG. 4, amplifier stage 78-1 in FIG. 5, etc.) of current-sharing amplifier stages to provide the voltage level for voltage V2 based on control input information. In such a manner, the headroom for the upper amplifier stage and consequently the headroom for the lower amplifier stage (e.g., amplifier stage 54-2 in FIG. 3, amplifier stage 66-2 or 68-2 in FIG. 4, amplifier stage 78-2 in FIG. 5, etc.) can be controlled and adjusted.

As shown in FIG. 6, control circuit 80 may include an operational amplifier 82 be configured to receive, at a first input, a target voltage and, at a first input, the current voltage level of voltage V2. Operational amplifier 82 may have an output that provides a bias voltage for the upper amplifier stage (e.g., for driving a bias transistor therein) based on the received input voltages.

A controller 84 such as a portion of control circuitry 14 in FIG. 1, and/or if desired, processor(s) 26 in FIG. 2 (e.g., a discrete or integrated component of control circuitry 14 and/or processor(s) 26) may provide the target voltage to the first input of operational amplifier 82 based on control input information. The control input information may be indicative of one or more scenarios for amplifier stage headroom adjustment. As just a few examples, the control input information may include indication(s) of a number of active antennas coupled to the upper amplifier stage of current-sharing amplifier stages and/or a number of active antennas coupled to the lower amplifier stage of current-sharing amplifier stages, indication(s) of gains (e.g., gain modes or settings) of the upper and/or lower amplifier stages of current-sharing amplifier stages, indication(s) of characteristics of signals to be processed by the upper and/or lower amplifier stages of current-sharing amplifier stages, indication(s) of operating modes of the upper and/or lower amplifier stages of current-sharing amplifier stages, etc.

Based on the control input information, controller 84 may provide a corresponding target voltage for operational amplifier 82. Based on the target voltage (e.g., provided based on the control input information) and the current voltage level of voltage V2, operational amplifier 82 may generate a corresponding bias voltage for the upper amplifier stage to drive the components (e.g., transistor(s)) therein, thereby adjusting supply voltage V2 (generated by the upper amplifier stage for the current-sharing path and received by operational amplifier 82) up or down. In some instances, supply voltage V2 may remain unchanged based on the generated bias voltage.

The configuration of a control circuit for controlling the upper amplifier stage to control (e.g., adjust) the supply voltage V2 provided on the current-sharing path between current sharing amplifier stages as shown in FIG. 6 is merely illustrative. If desired, other types of control circuits may be employed to dynamically adjust the supply voltage V2 provided on the current-sharing path.

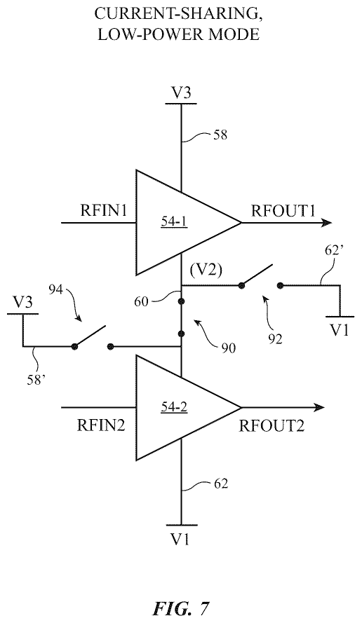

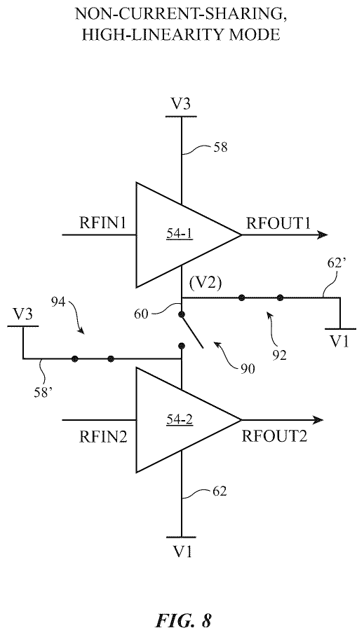

While current-sharing between amplifier stages may reduce power consumption, it may come at the cost of amplifier performance (e.g., due to reduced amplifier stage headroom). To better optimize amplifier operations in different scenarios, amplifier circuitry may be configured to exhibit different states for different modes of operation, such as current-sharing and non-current-sharing modes of operation. FIGS. 7 and 8 show an illustrative set of two amplifier stages coupled along different radio-frequency paths configurable to operate in a current-sharing mode and a non-current-sharing mode.

To be configurable to operate in the different modes of operation, the amplifier circuitry may include switching circuitry. Configurations in which amplifier circuitry having amplifier stages 54-1 and 54-2 (as described in connection with FIG. 3) incorporates the switching circuitry are described in connection with FIGS. 7 and 8 as an example. If desired, similarly configured switching circuitry may be incorporated into other types of amplifier circuitry (e.g., the amplifier circuitry of FIG. 4).

As shown in FIG. 7, switching circuitry (e.g., a switch 90 of the switching circuitry) may be coupled along (e.g., on, at a location along, etc.) current-sharing path 60 to selectively enable or disable current-sharing path 60 (e.g., enable or disable current-sharing of stage 54-1 with stage 54-2). The amplifier circuitry may include an additional voltage supply path 62′ coupled to the second supply voltage terminal of amplifier stage 54-1 (e.g., via a portion of path 60 between switch 90 and amplifier stage 54-1). When current-sharing path 60 is disabled, path 62′ may provide supply voltage V1 (e.g., a reference voltage such as a ground voltage) to the second supply voltage terminal of amplifier stage 54-1. In this context, path 62′ may sometimes be referred to as a non-current-sharing voltage supply path or simply a non-current-sharing path, since it is used instead of current-sharing path 60 to provide amplifier stage 54-1 with supply voltage in a non-current-sharing configuration. The switching circuitry (e.g., a switch 92 of the switching circuitry) may be coupled along (e.g., on, at a location along, etc.) non-current-sharing path 62′ to selectively enable or disable path 62′ in providing voltage V1 to amplifier stage 54-1.

The amplifier circuitry may include an additional voltage supply path 58′ coupled to the second supply voltage terminal of amplifier stage 54-2 (e.g., via a portion of path 60 between switch 90 and amplifier stage 54-2). When current-sharing path 60 is disabled, path 58′ may provide supply voltage V3 (e.g., a drain-side supply voltage) to the second supply voltage terminal of amplifier stage 54-2. In this context, path 58′ may sometimes be referred to as a non-current-sharing voltage supply path or simply a non-current-sharing path, since it is used instead of current-sharing path 60 to provide amplifier stage 54-2 with supply voltage in a non-current-sharing configuration. The switching circuitry (e.g., a switch 94 of the switching circuitry) may be coupled along (e.g., on, at a location along, etc.) non-current-sharing path 58′ to selectively enable or disable path 58′ in providing voltage V3 to amplifier stage 54-2.

An illustrative state of the switching circuitry (e.g., illustrative states of switches 90, 92, and 94) that provides a current-sharing configuration for a current-sharing mode of operation (sometimes referred to as a current-saving or low power mode of operation) is shown in the example of FIG. 7. In this state, switch 90 may be closed (e.g., in a closed or activated state that provides a conductive connection) and switches 92 and 94 may each be open (e.g., in an open or deactivated stage that provides a disconnection). Accordingly, in this current-sharing mode (as described in connection with FIG. 3), amplifier stage 54-1 may operate with a (fixed or variable) headroom that is the difference between voltages V3 and V2 and amplifier stage 54-2 may operate with a (fixed or variable) headroom that is the difference between voltages V2 and V1.

FIG. 8 shows the illustrative amplifier circuitry of FIG. 7, when the switching circuitry (e.g., switches 90, 92, and 94) therein exhibits a state (e.g., respective switch states) that provides a non-current-sharing configuration for a non-current-sharing mode of operation (sometimes referred to as a high-power, high-linearity, or high-performance mode of operation). In this state, switch 90 may be open (e.g., in an open or deactivated stage that provides a disconnection) and switches 92 and 94 may each be closed (e.g., in a closed or activated state that provides a conductive connection). Accordingly, in this non-current-sharing mode, amplifier stages 54-1 and 54-2 may each operate with a same fixed headroom that is the difference between voltages V3 and V1.

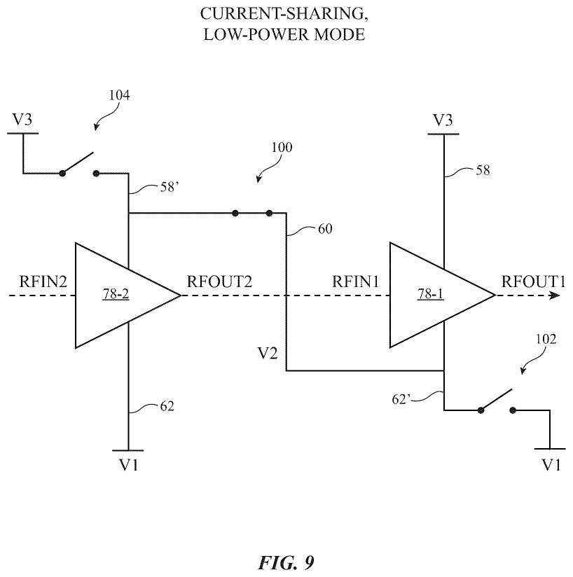

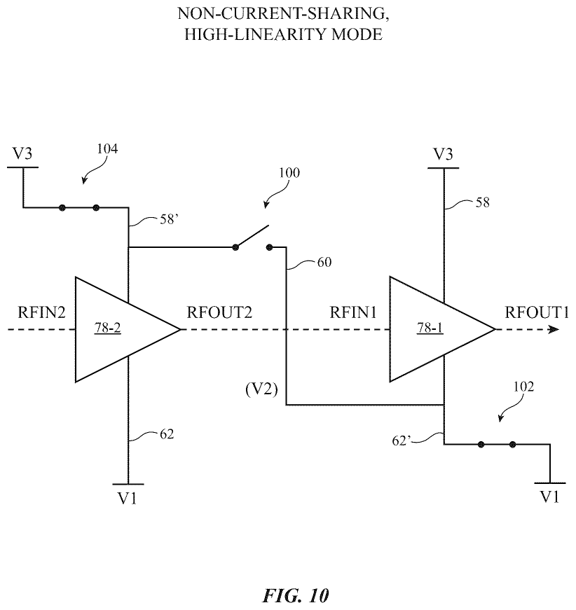

FIGS. 9 and 10 show an illustrative set of two amplifier stages coupled along the same radio-frequency path configurable to operate in a current-sharing mode and a non-current-sharing mode. To be configurable to operate in the different modes of operation, the amplifier circuitry may include switching circuitry. Configurations in which amplifier circuitry having amplifier stages 78-1 and 78-2 (as described in connection with FIG. 5) incorporates the switching circuitry are described in connection with FIGS. 9 and 10 as an example. If desired, similarly configured switching circuitry may be incorporated into other types of amplifier circuitry (e.g., other types of serially coupled or cascaded amplifier stages).

As shown in FIG. 9, switching circuitry (e.g., a switch 100 of the switching circuitry) may be coupled along (e.g., on, at a location along, etc.) current-sharing path 60 to selectively enable or disable current-sharing path 60 (e.g., enable or disable current-sharing of stage 78-1 with stage 78-2). The amplifier circuitry may include an additional voltage supply path 62′ coupled to a supply voltage terminal of amplifier stage 78-1 (e.g., via a portion of path 60 between switch 100 and amplifier stage 78-1). When current-sharing path 60 is disabled, path 62′ may provide supply voltage V1 (e.g., a reference voltage such as a ground voltage) to the supply voltage terminal of amplifier stage 78-1. In this context, path 62′ may sometimes be referred to as a non-current-sharing voltage supply path or simply a non-current-sharing path, since it is used instead of current-sharing path 60 to provide amplifier stage 78-1 with supply voltage in a non-current-sharing configuration. The switching circuitry (e.g., a switch 102 of the switching circuitry) may be coupled along (e.g., on, at a location along, etc.) non-current-sharing path 62′ to selectively enable or disable path 62′ in providing voltage V1 to amplifier stage 78-1.

The amplifier circuitry may include an additional voltage supply path 58′ coupled to a supply voltage terminal of amplifier stage 78-2 (e.g., via a portion of path 60 between switch 100 and amplifier stage 78-2). When current-sharing path 60 is disabled, path 58′ may provide supply voltage V3 (e.g., a drain-side supply voltage) to the supply voltage terminal of amplifier stage 78-2. In this context, path 58′ may sometimes be referred to as a non-current-sharing voltage supply path or simply a non-current-sharing path, since it is used instead of current-sharing path 60 to provide amplifier stage 78-2 with supply voltage in a non-current-sharing configuration. The switching circuitry (e.g., a switch 104 of the switching circuitry) may be coupled along (e.g., on, at a location along, etc.) non-current-sharing path 58′ to selectively enable or disable path 58′ in providing voltage V3 to amplifier stage 78-2.

An illustrative state of the switching circuitry (e.g., illustrative states of switches 100, 102, and 104) that provides a current-sharing configuration for a current-sharing mode of operation (sometimes referred to as a current-saving or low power mode of operation) is shown in the example of FIG. 9. In this state, switch 100 may be closed (e.g., in a closed or activated state that provides a conductive connection) and switches 102 and 104 may each be open (e.g., in an open or deactivated stage that provides a disconnection). Accordingly, in this current-sharing mode (as described in connection with FIG. 5), amplifier stage 78-1 may operate with a (variable) headroom that is the difference between voltages V3 and V2 and amplifier stage 78-2 may operate with a (variable) headroom that is the difference between voltages V2 and V1.

FIG. 10 shows the illustrative amplifier circuitry of FIG. 9, when the switching circuitry (e.g., switches 100, 102, and 104) therein exhibits a state (e.g., respective switch states) that provides a non-current-sharing configuration for a non-current-sharing mode of operation (sometimes referred to as a high-power, high-linearity, or high-performance mode of operation). In this state, switch 100 may be open (e.g., in an open or deactivated stage that provides a disconnection) and switches 102 and 104 may each be closed (e.g., in a closed or activated state that provides a conductive connection). Accordingly, in this non-current-sharing mode, amplifier stages 78-1 and 78-2 may each operate with a same fixed headroom that is the difference between voltages V3 and V1.

While not explicitly shown in FIGS. 7-10, the switching circuitry (e.g., switches) of amplifier circuitry may be coupled to control circuitry 14, processor(s) 26, and/or another type of controller that provides control signals to the switches based on control input information indicative of wireless communications circuitry operating conditions (e.g., control input information of the type described in connection with FIG. 6). In such a manner, the controller may, based on the control input information, place the switching circuitry in corresponding states such as states to enable or disable current-sharing (e.g., to control the switching circuitry to switch between the two states depicted in FIGS. 7 and 8, to control the switching circuitry to switch between the two stages depicted in FIGS. 9 and 10, etc.).

The methods and operations described above in connection with FIGS. 1-10 may be performed by the components of device 10 using software, firmware, and/or hardware (e.g., dedicated circuitry or hardware). Software code for performing these operations may be stored on non-transitory computer readable storage media (e.g., tangible computer-readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Wireless communications circuitry comprising:
a first amplifier stage configured to receive first radio-frequency signals and operate with first and second supply voltages to process the first radio-frequency signals;
a second amplifier stage coupled to the first amplifier stage and configured to receive second radio-frequency signals and operate with the second supply voltage and a reference voltage to process the second radio-frequency signals, wherein the first supply voltage and the reference voltage are fixed voltages and wherein the second supply voltage is a variable voltage.

2. The wireless communications circuitry of claim 1 further comprising:
a control circuit coupled to the first amplifier stage and configured to receive control input information and provide a bias voltage for the first amplifier stage to adjust the second supply voltage based on the control input information.

3. The wireless communications circuitry of claim 1, wherein the first amplifier stage is coupled along a first radio-frequency path and wherein the second amplifier stage is coupled along a second radio-frequency path that is parallel to the first radio-frequency path.

4. The wireless communications circuitry of claim 3, wherein the first radio-frequency path is coupled between a first set of one or more antennas and a radio-frequency combiner and wherein the second radio-frequency path is coupled between a second set of one or more antennas and the radio-frequency combiner.

5. The wireless communications circuitry of claim 4, wherein the second supply voltage is adjusted based on numbers of active antennas in the first and second sets of one or more antennas.

6. The wireless communications circuitry of claim 5, wherein the second supply voltage is at a first voltage level when a number of active antennas in the first set is greater than a number of active antennas in the second set, wherein the second supply voltage is at a second voltage level when the number of active antennas in the second set is greater than the number of active antennas in the first set, and wherein the first voltage level is less than the second voltage level.

7. The wireless communications circuitry of claim 1, wherein the first amplifier stage and the second amplifier stage are coupled serially along a same radio-frequency path.

8. The wireless communications circuitry of claim 7, wherein the second supply voltage is adjusted based on a gain exhibited by the first amplifier stage.

9. The wireless communications circuitry of claim 8, wherein the second supply voltage is at a first voltage level when the first amplifier stage exhibits a first gain, wherein the second supply voltage is at a second voltage level when the first amplifier stage exhibits a second gain less than the first gain, and wherein the first voltage level is less than the second voltage level.

10. Radio-frequency amplifier circuitry comprising:
a first amplifier stage;
a second amplifier stage;
a current-sharing path that couples the first amplifier stage to the second amplifier stage and that is configured to provide a supply voltage to the second amplifier stage; and
switching circuitry coupled along the current-sharing path and configured to exhibit a first state in which the current-sharing path is enabled and a second state in which the current-sharing path is disabled.

11. The radio-frequency amplifier circuitry of claim 10, wherein the supply voltage is a first supply voltage, wherein the first amplifier stage is configured to receive a second supply voltage and to operate using the first and second supply voltages, wherein the second amplifier stage is configured to receive a reference voltage and to operate using the first supply voltage and the reference voltage, and wherein the first supply voltage is between the second supply voltage and the reference voltage.

12. The radio-frequency amplifier circuitry of claim 11 further comprising:
a first non-current-sharing path coupled to the first amplifier stage and configured to provide the reference voltage to the first amplifier stage; and
a second non-current-sharing path coupled to the second amplifier stage and configured to provide the second supply voltage to the second amplifier stage.

13. The radio-frequency amplifier circuitry of claim 12, wherein the switching circuitry comprises a first switch coupled along the current-sharing path, a second switch coupled along the first non-current-sharing path, and a third switch coupled along the second non-current-sharing path.

14. The radio-frequency amplifier circuitry of claim 13, wherein the first switch is closed, the second switch is open, and the third switch is open in the first state of the switching circuitry and wherein the first switch is open, the second switch is closed, and the third switch is closed in the second state of the switching circuitry.

15. The radio-frequency amplifier circuitry of claim 11, wherein the first supply voltage is a variable voltage and wherein the second supply voltage and the reference voltage are fixed voltages.

16. The radio-frequency amplifier circuitry of claim 10, wherein the first amplifier stage is coupled along a first radio-frequency path and wherein the second amplifier stage is coupled along a second radio-frequency path that is parallel to the first radio-frequency path.

17. The radio-frequency amplifier circuitry of claim 10, wherein the first amplifier stage and the second amplifier stage are coupled serially along a same radio-frequency path.

18. Wireless communications circuitry comprising:
first amplifier circuitry coupled along a first radio-frequency path and configured to receive a first supply voltage, generate a second supply voltage, and process a first radio-frequency signal based on the first and second supply voltages; and
second amplifier circuitry coupled to the first amplifier circuitry, coupled along a second radio-frequency path that is parallel to the first radio-frequency path, and configured to receive the second supply voltage from the first amplifier circuitry, receive a reference voltage, and process a second radio-frequency signal based on the second supply voltage and the reference voltage.

19. The wireless communications circuitry of claim 18, further comprising:
a radio-frequency combiner, wherein the first amplifier circuitry is coupled to a first input of the radio-frequency combiner and wherein the second amplifier circuitry is coupled to a second input of the radio-frequency combiner.

20. The wireless communications circuitry of claim 18, wherein the first supply voltage and the reference voltage are fixed voltages and wherein the second supply voltage is a variable voltage.
